(19) United States
(12) Patent Application Publication
(10) Pub. No.: US 2026/0197005 A1
(43) Pub. Date: Jul. 9, 2026

(54) CRYSTAL-LESS TRANSCEIVER JITTER MITIGATION

(71) Applicant: Infineon Technologies Americas Corp., El Segundo, CA (US)

(72) Inventor: Venkateswara Penumuchu, Pleasanton, CA (US)

(73) Assignee: Infineon Technologies Americas Corp., El Segundo, CA (US)

(21) Appl. No.: 19/391,846

(22) Filed: Nov. 17, 2025

Related U.S. Application Data
(60) Provisional application No. 63/742,720, filed on Jan. 7, 2025.

(51) Int. Cl. H03L 7/08; H03L 7/099; H03L 7/107; H03L 7/187

(52) U.S. Cl. CPC H03L 7/0807; H03L 7/0991; H03L 7/107; H03L 7/187

(57) ABSTRACT

A system includes a crystal oscillator, a central switch transceiver coupled to the crystal oscillator, and a sensor transceiver. The central switch transceiver includes a transmitter circuit to employ a timing reference from the crystal oscillator to generate a self-clocking signal carrying first data and a clock and data recovery loop circuit to operate at a first bandwidth to sample second data received from the sensor transceiver. The sensor transceiver includes a reference clock recovery circuit to decode, from the self-clocking signal, a reference clock. A phase-locked loop (PLL) circuit generates a transmission clock, from the reference clock, operating at second bandwidth, for use in generating the second data. The first bandwidth is greater than or equal to a second bandwidth of the PLL circuit to mitigate jitter experienced by the clock and data recovery loop circuit due to jitter in the transmission clock.

### CROSS-REFERENCE TO RELATED APPLICATIONS

This application claims priority to U.S. Application No. 63/742,720, titled Method to Combat Jitter in Asymmetric Crystal Less Wire Line Transceivers, filed Jan. 7, 2025, which is hereby incorporated by reference in its entirety.

### FIELD OF INVENTION

The present disclosure relates to electronic data transmission systems over wireline media, and more particularly to mitigating jitter in crystal-less transceiver pairs where one transceiver operates without a crystal timing reference.

### BACKGROUND

High-speed data communication systems typically employ transceivers that rely on crystal oscillators to provide stable and precise timing references for data transmission and reception. Crystal oscillators are favored for their high-quality factor and ability to generate low-jitter clock signals that enable reliable high-frequency operation. In some transceiver designs, each transceiver includes its own crystal oscillator to maintain independent timing control and minimize dependency on external timing sources.

In many modern applications, such as automotive sensor networks, multiple sensor devices are distributed throughout a system and communicate with a central processing unit or switch. These applications often involve asymmetric data transmission requirements, where data rates differ significantly between the uplink and downlink directions. For instance, sensor devices may need to transmit large amounts of high-rate sensor data to a central unit while receiving relatively low-rate control or configuration data in return.

The inclusion of individual crystal oscillators in each sensor device can present challenges in terms of cost, complexity, and reliability. Crystal components add expense to each sensor unit, and their mechanical nature can introduce potential failure points in harsh operating environments. Additionally, maintaining synchronization across multiple independent crystal-based timing sources can introduce system-level complexity.

To address these challenges, crystal-less transceiver architectures have been developed where one transceiver in a communication pair operates without a local crystal oscillator. In such systems, timing information is conveyed from a crystal-equipped transceiver to the crystal-less transceiver through self-clocking signaling schemes, such as Manchester coding, which embed clock information within the transmitted data stream. Recovering or extracting a reference clock from self-clocking signals, however, typically causes significant jitter, which can be propagated in communications signals carrying sensor data back to the crystal-based transceiver.

### BRIEF DESCRIPTION OF FIGURES

Non-limiting and non-exhaustive examples are described with reference to the following figures.

FIG. 1 is a block diagram of a system for reducing jitter in data communication between a central switch and multiple sensors according to some embodiments.

FIG. 2 is a block diagram of a central switch transceiver in a communication system according to some embodiments.

FIG. 3A shows a block diagram of a sensor transceiver in a crystal-less configuration according to some embodiments.

FIG. 3B is a block diagram of the phase locked-loop (PLL) circuit of FIG. 3A according to some embodiments.

FIG. 3C is an example of the reference clock recovery circuit configured to extract a reference clock from a Manchester-encoded signal according to some embodiments.

FIG. 4 is a graph illustrating PLL output jitter (measured and estimated) for various PLL reference clock input jitters and PLL loop bandwidths according to some embodiments.

FIG. 5 is a graph illustrating the relationship between reference jitter and residual jitter for various PLL and CDR bandwidths according to some embodiments.

FIG. 6 depicts a flowchart for a method of mitigating jitter in crystal-less wireline transceivers according to some embodiments.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

As discussed, recovering or extracting a reference clock from self-clocking signals typically causes significant jitter, which can be propagated in communications signals sent back to the crystal-based transceiver. For example, recovering timing information from self-clocking signals may introduce timing uncertainties and jitter that can degrade system performance. The recovered clock signal typically exhibits greater jitter compared to signals generated directly from crystal oscillators. When this jittery reference clock is used to generate high-frequency transmission clocks through phase-locked loop circuits, for example, the jitter can propagate and affect the quality of transmitted signals. The receiving or central switch transceiver must then track and compensate for this jitter to maintain reliable data recovery, presenting challenges for maintaining acceptable signal-to-noise (SNR) ratios in high-speed communication links.

The present disclosure describes aspects, systems, and methods for mitigating jitter in crystal-less wireline transceivers, which may be more pronounced, among mitigating other deficiencies that will be apparent to those skilled in the art. In such systems, a central switch may include central switch transceivers and a common crystal oscillator coupled to the central switch transceivers. The common crystal oscillator may generate a timing reference such as a reference clock. The central switch transceiver may generate a self-clocking signal carrying data and the reference clock generated by the crystal oscillator. Each central switch transceiver may communicate with a sensor transceiver that operates without individual crystal oscillators, thereby reducing cost and improving reliability in applications such as automotive sensor networks.

The central switch transceivers may each include a clock and data recovery (CDR) loop circuit configured to operate at a first bandwidth to sample data received from a sensor transceiver. The CDR loop circuit may recover high data rate information transmitted by a sensor transceiver using respective transmission clocks generated by their phase-locked loop (PLL) circuits. A first bandwidth of the CDR loop circuit may determine its ability to track and compensate for timing variations in the received signals from the sensor transceiver.

A sensor transceiver in the system may include a reference clock recovery circuit configured to extract the reference clock from the self-clocking signal received from a central switch transceiver. The self-clocking signal may carry timing information embedded within the data transmission, enabling the sensor transceiver to derive timing references without requiring use of a local crystal oscillator. The reference clock recovery circuit may decode the timing information from the self-clocking signal to generate the reference clock.

The sensor transceiver may further include a PLL circuit configured to generate a high frequency transmission clock from the reference clock. The PLL circuit may use the reference clock as an input to produce a higher frequency clock signal (also referred to herein as a transmission clock) suitable for high data rate transmissions back to the central switch transceiver. The PLL circuit may have a second bandwidth that affects how the PLL circuit responds to jitter present in the reference clock signal as well as how the CDR loop circuit is able to track the jitter to accurately decode data from the high data rate transmissions.

In some embodiments, the first bandwidth of the CDR loop circuit is configured to be greater than or equal to the second bandwidth of the PLL circuit to mitigate jitter experienced by the CDR loop circuit. This bandwidth relationship may enable the central switch transceiver to effectively track and compensate for jitter that originates from the PLL circuit of the sensor transceiver. When the PLL circuit operates at a lower bandwidth, in relation to the first bandwidth, the jitter spectrum may be constrained to lower frequencies, which the higher bandwidth CDR loop circuit may be capable of tracking without degrading signal-to-noise ratios.

The central switch transceiver may operate as a system component that uses a common crystal oscillator configured to generate a timing reference and a transmitter circuit configured to generate the self-clocking signal carrying low data rate information using that timing reference. The central switch transceiver may also include a receiver circuit, which in turn includes the CDR loop circuit configured to operate at the first bandwidth to recover high data rate information from the sensor transceiver. In some embodiments, asymmetric data rates enable efficient communication where low data rate control information flows from the central switch transceiver to the sensor transceiver, while high data rate sensor information and data flow from the sensor transceiver back to the central switch transceiver.

The sensor transceiver may operate as a system component that includes the reference clock recovery circuit configured to extract the reference clock from the self-clocking signal received from the central switch transceiver. The sensor transceiver may also include the PLL circuit having a bandwidth that may be less than or equal to that of the CDR loop circuit bandwidth of the central switch transceiver. The sensor transceiver may include a transmitter circuit configured to transmit high data rate information using the high frequency transmission clock generated by the PLL circuit. This configuration may enable crystal-less operation while maintaining acceptable jitter performance through coordinated bandwidth management between the central switch transceiver and sensor transceiver. The ability to employ sensors with crystal-less sensor transceivers reduces system costs and complexity and increases system reliability. These and other advantages will be apparent to those skilled in the art of networked sensor design (such as in automobiles and other vehicles or systems) in view of the following detailed explanation of the various figures.

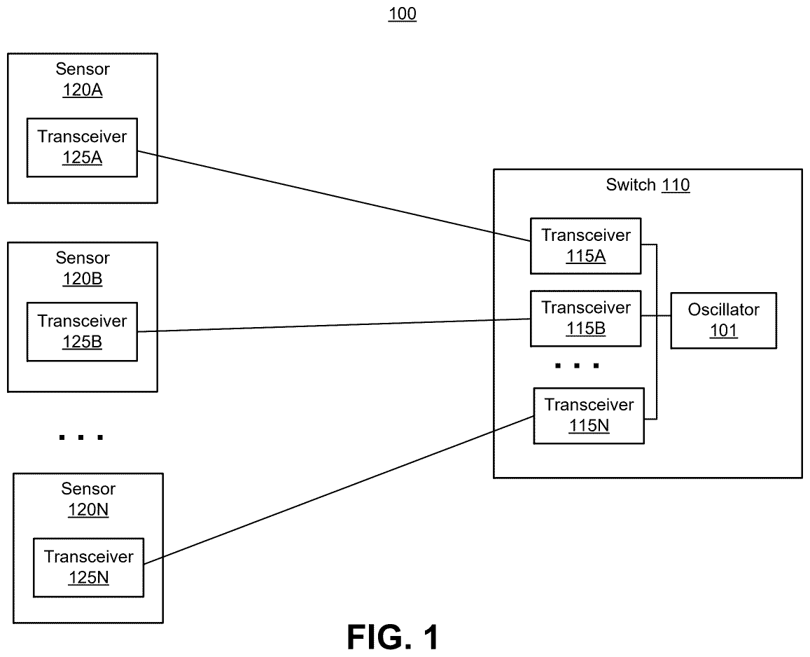

Referring to FIG. 1, a system 100 may be configured for reducing jitter in data communication between a central switch and multiple sensors in some embodiments, such as in automotive applications. In embodiments, the data communication is data-rate asymmetric, as will be explained, although this need not be the case to achieve value from employing the principles described herein. The system 100 may be designed for automotive applications such as self-driving cars where numerous sensors surround the vehicle and transmit data to a central or zonal switch. In some cases, the system 100 may implement the 803.2dm standard, which specifies asymmetrical electrical Ethernet physical layers (PHYs) optimized for automotive applications, specifically for end-node cameras and displays.

The system 100 may include a switch 110 and a plurality of sensors 120A, 120B, through 120N (e.g., sensors 120A-120N). The switch 110 may include central switch transceivers 115A, 115B through 115N (e.g., central switch transceivers 115A-115N) that each communicate with a sensor through respective communication links. A sensor 120A may include a sensor transceiver 125A, a sensor 120B may include a sensor transceiver 125B, and a sensor 120N may include a sensor transceiver 125N. The central switch transceivers 115A-115N may be communicatively coupled to the sensor transceivers 125A-125N, respectively, through the communication links to enable bidirectional data transmission.

In the asymmetric data communication configuration shown in FIG. 1, the central switch transceivers 115A-115N may transmit low data rate (LDR) signals to the sensor transceivers 125A-125N, respectively, using a self-clocking signaling scheme. The sensor transceivers 125A-125N may transmit high data rate (HDR) signals back to the central switch transceivers 115A-115N, respectively, where the high data rate may be higher than the low data rate. This asymmetric configuration may enable efficient bandwidth utilization where control information and timing references flow at lower data rates from the central switch transceivers 115A-115N to the sensor transceivers, while sensor data flows at higher data rates from the sensor transceivers back to the central switch transceivers 115A-115N.

The central switch 110 may also include a common crystal oscillator 101 to provide a stable timing reference, which may be conveyed to the sensor transceivers 125A-125N through the self-clocking signals. Each of the sensor transceivers 125A-125N may operate without an individual crystal oscillator, instead deriving their timing reference from the self-clocking signals received from the central switch transceivers 115A-115N, respectively. The self-clocking signals may carry timing information embedded within the data transmission, enabling the sensor transceivers to extract both data and timing references from the same signal. This architecture may enable cost-effective and reliable operation by eliminating the need for individual crystals at each sensor location while maintaining synchronized operation across the system 100.

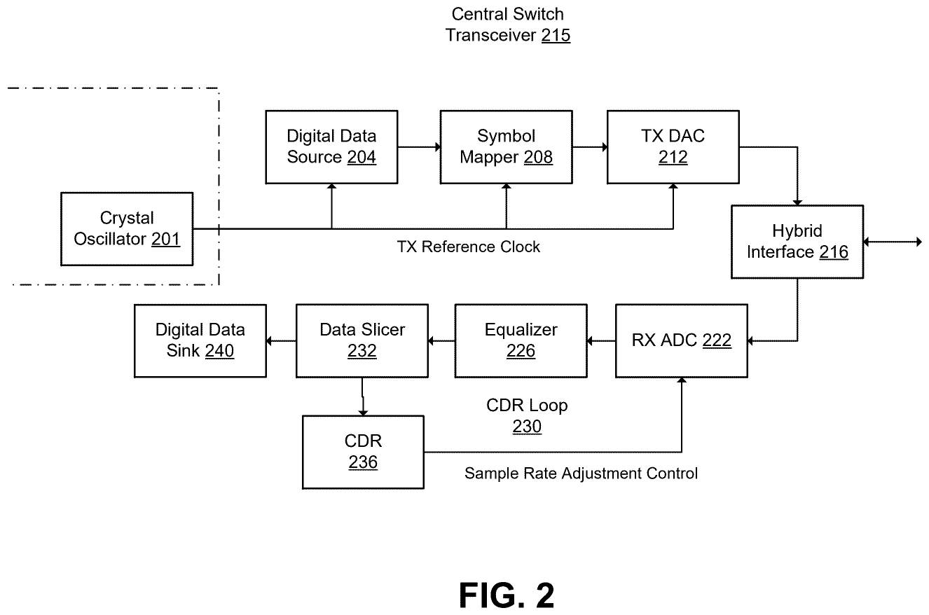

Referring to FIG. 2, a central switch transceiver 215 may be configured to provide stable timing references and manage bidirectional communication in the system 100. The central switch transceiver 215 may be any of the central switch transceivers 115A-115N (FIG. 1). The central switch transceiver 215 may be coupled to a common crystal oscillator 201 (such as the common crystal oscillator 101) that provides a timing reference for the system 100, e.g., which may be a clock reference or signal. Although not illustrated, a separate crystal oscillator may integrated within each central switch transceiver 115A-115N or 215, although this is less cost effective and may involve synchronization of all of the crystal oscillators. In some cases, the crystal oscillator 201 may operate at low frequencies such as 25-50 megahertz (MHz) to generate local clock synchronization with the switch clock. The crystal oscillator 201 may provide a stable and precise timing reference that serves as the foundation for generating self-clocking signals transmitted to the sensor transceivers 125A-125N.

A digital data source 204 may generate digital data for transmission to any of the sensor transceivers 125A-125N. The digital data source 204 may include framing and channel coding functionality for higher layer protocols, enabling proper data structuring and error correction capabilities. The digital data from the digital data source 204 may be provided to a symbol mapper 208, which maps the digital data into symbols suitable for transmission using a self-clocking signaling scheme. In some embodiments, the symbol mapper 208 implements Manchester coding to create the self-clocking signal, where the self-clocking signal includes Manchester coding that embeds timing information within the data transmission.

The output of the symbol mapper 208 may be connected to a transmission digital-to-analog converter or TX DAC 212, which converts the digital signal into an analog signal for transmission. The TX DAC 212 may receive timing synchronization from the common crystal oscillator 201 to maintain precise timing alignment during the digital-to-analog conversion process. The transmitter circuit, which may include the digital data source 204, the symbol mapper 208, and the TX DAC 212, may be configured to operate at a low data rate for transmission to the sensor transceivers in an asymmetric communication configuration.

The central switch transceiver 215 may further include a hybrid interface circuit 216 that enables transmission and reception over a single differential pair of conducting medium. The hybrid interface circuit 216 may be connected to both the TX DAC 212 for transmitting signals to any of the sensors 120A-120N and to a receiving analog-to-digital converter or RX ADC 222 for receiving signals from any of the sensors 120A-120N, enabling duplex communication over the single differential pair. The hybrid interface circuit 216 may separate transmitted and received signals to prevent interference between the transmit and receive paths while allowing simultaneous bidirectional communication.

On the receive path, the RX ADC 222 may receive analog signals from the hybrid interface circuit 216 and convert the analog signals into digital signals for processing. The RX ADC 222 may receive timing synchronization to maintain proper sampling of the incoming high data rate signals from the sensor transceivers. The output of the RX ADC 222 may be provided to an equalizer 226, which processes the digital signal to remove inter-symbol interference and prepare the signal for data recovery.

The equalized signal from the equalizer 226 may be provided to a data slicer 232, which converts the digital signal into data symbols for further processing. A CDR circuit 236 may detect phase errors in the received signal and generate sample rate adjustment control signals to maintain proper timing alignment. The CDR circuit 236 may be part of a CDR loop circuit 230 that includes the RX ADC 222, the equalizer 226, the data slicer 232, and the CDR circuit 236.

The CDR loop circuit 230 may operate at a first bandwidth to recover high data rate information from any of the sensor transceivers 125A-125N. For example, the high data rate information may be used for data reception from the sensor transceivers 125A-125N and be higher than the low data rate used for transmission to the sensor transceivers 125A-125N. The first bandwidth of the CDR loop circuit 230 may be configured to track and compensate for band-limited jitter generated by PLL circuits of the sensor transceivers 125A-125N. In some cases, the band-limited jitter may include low-frequency jitter components that survive low-pass filtering by the PLL bandwidth of the sensor transceivers 125A-125N. The recovered data symbols from the data slicer 232 may be provided to a digital data sink 240 for further processing and consumption of the high data rate information received from the sensor transceivers 125A-125N.

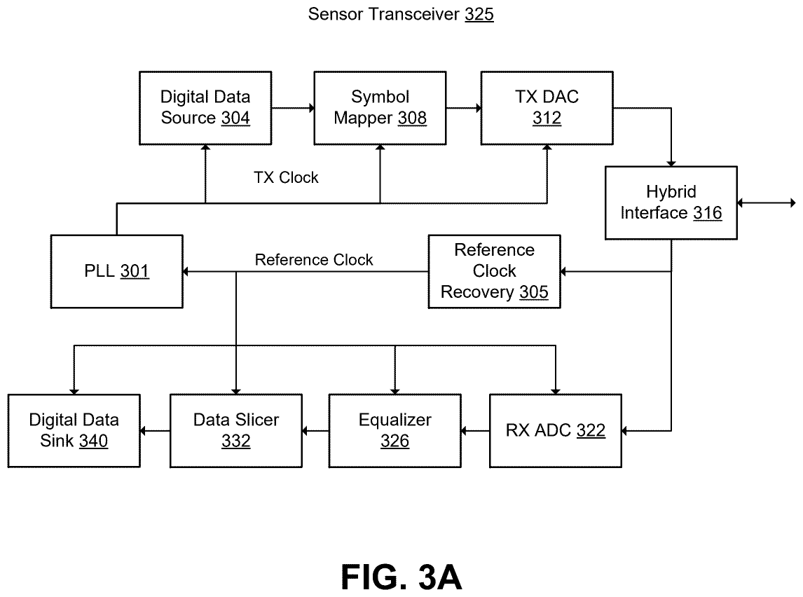

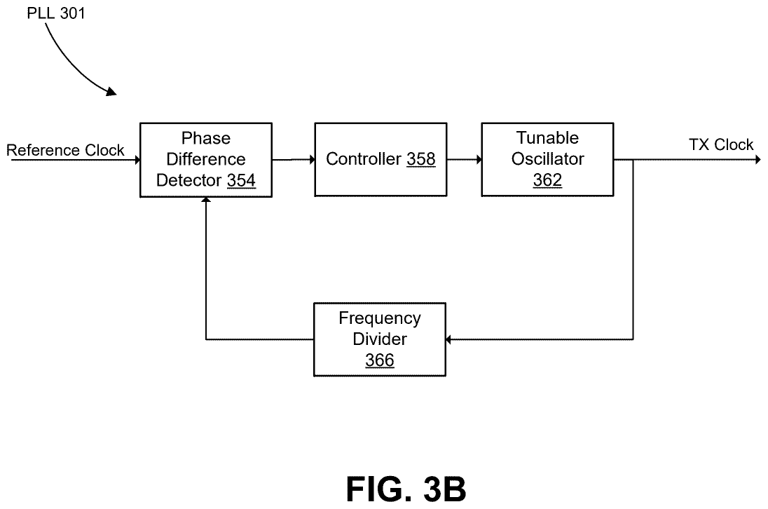

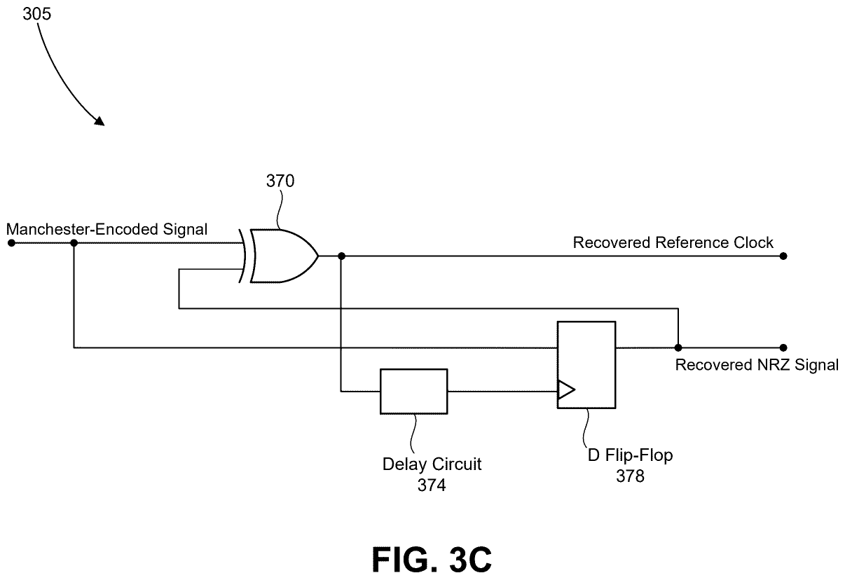

In some embodiments, the first bandwidth of the CDR loop circuit 230 is configured to be greater than or equal to the second bandwidth of the PLL circuit (301 in FIG. 3A) to mitigate jitter experienced by the CDR loop circuit 230. When bandwidth is referred to herein for CDR, it may be with reference to CDR loop ability to track the jitter frequency range up to a certain limit with loss of no more than 1 decibel (dB) signal to noise ratio (SNR) in a jitter-limited receiver. That limit may be referred 1 dB CDR bandwidth or simply CDR bandwidth. This mean sinusoidal jitters with frequencies up to the CDR bandwidth, even when their amplitudes large enough to prevent normal receiver operation if their frequencies are outside CDR bandwidth, may cause no more than a 1 dB SNR drop. In embodiments, the PLL circuit 301 functions as a low-pass filter for an input phase noise and a high-pass filter for phase noise from a voltage controlled oscillator (VCO), which will be discussed with reference to FIGS. 3A-3B. When bandwidth is referred with reference to the PLL, it may be with reference to the 3 dB cutoff frequency for the above-mentioned low pass or high pass transfer functions. In this way, the PLL reference clock phase noise is low-pass filtered while the VCO phase noise is high-pass filtered.

Referring to FIG. 3A, a sensor transceiver 325 may be configured to operate without a crystal oscillator while maintaining high data rate transmission capabilities. The sensor transceiver 325 may represent any of the sensor transceivers 125A, 125B, or 125N in the system 100 (see FIG. 1). The sensor transceiver 325 may be designed to extract timing references from self-clocking signals received from the central switch transceiver 215 and generate high frequency transmission clocks for transmitting sensor data back to the central switch transceiver 215.

The sensor transceiver 325 may include a digital data source 304 that generates high data rate digital data for transmission to the central switch transceiver 215. The digital data source 304 may include video sensors and lidar sensors as examples of high-speed data generating sensors that collect information in automotive applications. The digital data source 304 may also include framing and channel coding functionality for higher layer protocols, enabling proper data structuring and error correction capabilities for the high data rate transmissions. The digital data source 304 may connect to a symbol mapper 308, which maps the high data rate data symbols into a digital signal format suitable for transmission.

The symbol mapper 308 may output to a TX DAC 312, which may be a transmit digital-to-analog converter that converts the high data rate digital signal to a high data rate analog signal for transmission. The TX DAC 312 may include digital-to-analog converter circuitry configured to use a transmission clock in generating the high data rate data transmitted back to the central switch transceiver 215. The TX DAC 312 may receive timing synchronization from a PLL circuit 301 to maintain precise timing alignment during the digital-to-analog conversion process for the high data rate transmissions.

The sensor transceiver 325 may include the PLL circuit 301 that receives a reference clock from a reference clock recovery circuit 305. The reference clock recovery circuit 305 may extract timing information from a Manchester-encoded signal received from the central switch transceiver 215 through a hybrid interface circuit 316 that communicates with the hybrid interface circuit 216 of the central switch transceiver 215. The Manchester-encoded signal may be the self-clocking signal that includes Manchester coding, where the Manchester coding embeds timing information within the data transmission to enable crystal-less operation. The PLL circuit 301 may generate a transmission clock signal that may be distributed to the digital data source 304, the symbol mapper 308, and the TX DAC 312 to synchronize the transmission path operations.

The reference clock recovery circuit 305 may include a Manchester decoder configured to decode Manchester encoding in the self-clocking signal received from the central switch transceiver 215. The self-clocking signal may be received at a low data rate from the central switch transceiver 215, while the high data rate information generated by the sensor transceiver 325 may be transmitted at a rate that may be higher than the low data rate. This asymmetric data rate configuration may enable efficient communication where timing and control information flows at lower data rates to the sensor transceiver 325, while sensor data flows at higher data rates from the sensor transceiver 325 back to the central switch transceiver 215.

The sensor transceiver 325 may further include the hybrid interface circuit 316 that enables simultaneous transmission and reception over a single differential pair of conducting medium. The hybrid interface circuit 316 may connect to both the TX DAC 312 for transmitting signals to the central switch transceiver 215 and to an RX ADC 322 for receiving signals from the central switch transceiver 215, enabling full duplex communication over the single differential pair. The hybrid interface circuit 316 may separate transmitted and received signals to prevent interference between the transmit and receive paths while allowing bidirectional communication with the central switch transceiver 215.

The receive path of the sensor transceiver 325 may include the RX ADC 322, which may be a receive analog-to-digital converter that receives timing synchronization and converts incoming analog signals to digital form. The RX ADC 322 may receive the self-clocking signal through the hybrid interface circuit 316 and convert the analog signal into digital signals for processing by the reference clock recovery circuit 305. An equalizer 326 may be connected to the output of the RX ADC 322 and may perform equalization to remove inter-symbol interference from the received low data rate signal.

The equalized signal from the equalizer 326 may be provided to a data slicer 332, which recovers the low data rate digital data from the received signal. The data slicer 332 may convert the equalized digital signal into data symbols for further processing. The data slicer 332 may output to a digital data sink 340, which processes the received low data rate data from the central switch transceiver 215. The digital data sink 340 may include functionality for frame boundary identification and channel decoding to properly process the control and timing information received from the central switch transceiver 215.

Referring to FIG. 3B, the PLL circuit 301 (FIG. 3A) may include a detailed architecture configured to generate a high frequency transmission clock from the reference clock extracted by the reference clock recovery circuit 305. The PLL circuit 301 may include a phase difference detector 354, a controller 358, a tunable oscillator 362, and a frequency divider 366. The phase difference detector 354 may receive the reference clock signal from the reference clock recovery circuit 305 and a feedback signal from the frequency divider 366 to identify a phase difference between these two input signals.

The phase difference detector 354 may compare the phase of the reference clock with a divided output from the tunable oscillator 362 and generate a phase error signal that represents the timing difference between the reference and feedback signals. The phase error signal from the phase difference detector 354 may be provided to the controller 358, which may be configured to adjust the tunable oscillator 362 based on the phase difference. The controller 358 may process the phase difference information and generate a control signal that adjusts the frequency and phase of the tunable oscillator 362 to minimize the phase error between the reference and feedback signals.

The tunable oscillator 362 may generate a high-frequency output clock signal based on the control signal from the controller 358. In some embodiments, the tunable oscillator 362 is implemented as a voltage controlled oscillator (VCO) that contributes intrinsic jitter to the system. The tunable oscillator 362 may use LC/RC oscillator design that can operate at high frequency but may be less stable compared to crystal oscillators. The high-frequency output from the tunable oscillator 362 may serve as the transmission clock for the sensor transceiver 325 and may be distributed to the digital data source 304, the symbol mapper 308, and the TX DAC 312.

The frequency divider 366 may be positioned in a feedback path and may be configured to divide the tunable oscillator 362 output (or voltage controlled oscillator output) by an integer factor. The frequency divider 366 may create the feedback signal that is provided to the phase difference detector 354 for phase comparison with the reference clock. The integer division factor of the frequency divider 366 may represent the ratio of HDR clock rate to recovered clock rate, establishing the relationship between the high data rate transmission frequency and the low data rate reference clock frequency. In some cases, the transmission clock frequency may equal the integer factor times the recovered clock frequency.

The bandwidth of the PLL circuit 301 may be determined by a transfer function of the controller 358, a loop gain, and a rate of the reference clock. The controller 358 may implement a transfer function that affects how the PLL circuit 301 responds to phase errors and timing variations in the reference clock signal. Higher reference clock rates may enable wider loop bandwidths, while the loop gain may determine the responsiveness of the PLL circuit 301 to phase corrections. The PLL circuit 301 transfer function may exhibit low-pass characteristics for reference jitter and high-pass characteristics for VCO jitter, where reference jitter may be filtered through the low-pass response while VCO jitter may be passed through the high-pass response.

The second bandwidth of the PLL circuit 301 may be configured to be less than or equal to the first bandwidth of the CDR loop circuit 230 to enable effective jitter mitigation. In some embodiments, the second bandwidth may be set sufficiently low to filter out residual jitter measurable from the first bandwidth to a Nyquist frequency of the PLL circuit 301. The residual jitter may represent the amount of jitter measured from the first bandwidth of the CDR loop circuit 230 to the Nyquist frequency of the PLL circuit 301, where this residual jitter may cause signal-to-noise ratio degradation in the high data rate receiver if not properly managed. The Nyquist frequency may be defined as half the sampling rate of the PLL circuit 301, representing the highest frequency that can be accurately represented without aliasing.

In some cases, the second bandwidth may be set to as low as a few tens of kilohertz (KHz), while the PLL circuit 301 itself may be operating at a few tens or hundreds of megahertz (Mhz) to achieve target jitter filtering characteristics. By constraining the second bandwidth to a lower value, the PLL circuit 301 may limit the jitter frequency spectrum to lower frequencies that the CDR loop circuit 230 can effectively track and for which to compensate. When the second bandwidth is sufficiently lower than the first bandwidth, the jitter generated by the self-clocking scheme may be band-limited to frequencies that the higher bandwidth CDR loop circuit 230 can track without causing degradation to the signal-to-noise ratio of the receiver of the central switch transceiver 215.

Referring to FIG. 3C, the reference clock recovery circuit 305 may be configured to extract timing information from the self-clocking signal received from the central switch transceiver 215. The reference clock recovery circuit 305 may include an XOR gate 370, a delay circuit 374, and a D flip-flop 378 that work together to recover both clock and data information from the Manchester-encoded signal.

There may be always a transition at the middle of Manchester encoded symbol. For example, a logic 1 may have a low-to-high transition. Logic 0 may have a high-to-low transition. The XOR gate 370 may receive the self-clocking signal at one input and NRZ (recovered binary non-return to zero of the self-clocking signal) at another input. The Manchester encoded signal may output directly as the recovered reference clock when the recovered NRZ signal is logic 0, for example. The inverted Manchester encoded signal may output the recovered reference clock when the recovered NRZ signal is a logic 1. The transition at the middle of the current Manchester symbol may generate the clocking edge to the D flip-flop 378 to recover the next NRZ signal logic level.

The delay circuit 374 delay may be set such that the D flip-flop 378 samples at a particular phase of Manchester signal to recover the NRZ signal. This configuration may enable the reference clock recovery circuit 305 to simultaneously extract both the reference clock for timing synchronization and the NRZ data signal for data processing from the same self-clocking signal received from the central switch transceiver 215. The Manchester encoding may embed timing information within the data transmission by using signal transitions to represent both clock edges and data bits, enabling the sensor transceiver 325 to derive timing references without requiring a local crystal oscillator.

The reference clock recovery circuit 305 may experience jitter in the recovered reference clock due to several sources of interference and noise. Thermal noise in the receiver circuitry may introduce random variations in the timing extraction process, causing uncertainty in the recovered clock edges. Residual echo of the output of the TX DAC 312 may interfere with the received self-clocking signal, where incomplete cancellation of the transmitted high data rate signal may create timing disturbances in the reference clock recovery process. Inter-symbol interference (ISI) in the self-clocking signal may cause timing variations due to signal distortion from the transmission channel, where previous symbols may affect the timing extraction of current symbols.

The jitter in the recovered reference clock may be approximately two orders of magnitude higher compared to the jitter of a crystal clock reference, presenting challenges for maintaining timing accuracy in the sensor transceiver 325. The combination of thermal noise, residual echo, and inter-symbol interference may create a white noise spectrum in the reference jitter, where the jitter power may be distributed across a wide frequency range. This white reference jitter may serve as input to the PLL circuit 301, where the low-pass characteristics of the PLL circuit 301 may filter the jitter spectrum and constrain the output jitter to lower frequencies that the CDR loop circuit 230 can track and compensate for effectively.

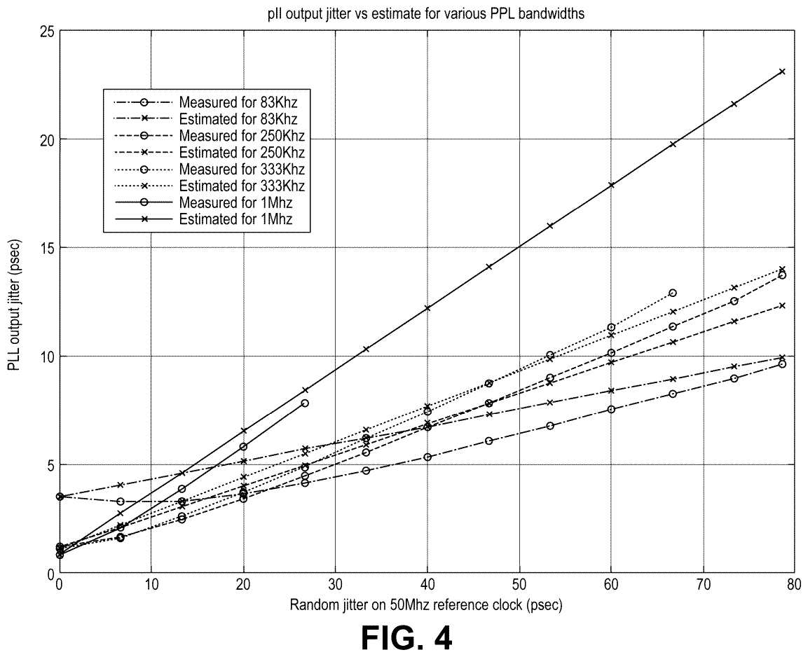

In FIG. 4, a graph illustrates the relationship between reference jitter and PLL output jitter for various PLL bandwidths, demonstrating how different bandwidth configurations affect jitter propagation through the PLL circuit 301. The graph depicts PLL output jitter measured in picoseconds on the vertical axis versus random jitter on a 50 MHz reference clock measured in picoseconds on the horizontal axis. The graph displays multiple curves representing both measured and estimated jitter values for different PLL bandwidths including 83 KHz, 250 KHz, 333 KHz, and 1 MHz configurations.

As shown in FIG. 4, the curves demonstrate that as the random jitter on the reference clock increases, the PLL output jitter also increases, with higher PLL bandwidths generally resulting in greater output jitter for a given amount of input jitter. The measured values, shown with circular markers and solid lines, correlate closely with the estimated values, shown with x markers and dotted lines, for each bandwidth configuration throughout the range of input jitter values. This correlation validates the predictive relationship between reference jitter input and PLL output jitter across different bandwidth settings.

The white spectrum reference jitter from the reference clock recovery circuit 305 may be filtered by the low-pass transfer function of the PLL circuit 301, where the PLL circuit 301 acts as a low-pass filter for input phase noise and jitter. The low-pass filtering characteristics of the PLL circuit 301 may constrain the reference jitter contribution at the PLL output to frequencies below the second bandwidth of the PLL circuit 301. When the reference jitter exhibits a white noise spectrum with uniform power distribution across frequencies, the low-pass filtering effect may reduce the total jitter power that propagates to the PLL output by limiting the frequency range of the jitter components.

The mathematical relationship between input jitter and output jitter of the PLL circuit 301 may be expressed by the formula:

$${J}_{out} = {J}_{in} \cdot \sqrt{\frac{{F}_{pll}}{{F}_{signal}}} + {J}_{vco} ,$$

where Jᵢₙ represents the input jitter into the PLL circuit 301, Jₒᵤₜ represents the output jitter from the PLL circuit 301, J_{vco} represents the VCO intrinsic jitter contributed by the tunable oscillator 362, Fₚₗₗ represents the second bandwidth of the PLL circuit 301, and F_{signal} represents the Nyquist frequency of the clock edge signal. The Nyquist frequency may be defined as half the edge rate of the transmission clock generated by the PLL circuit 301.

This formula demonstrates that lowering the second bandwidth Fₚₗₗ of the PLL circuit 301 may reduce the contribution of reference jitter at the PLL output through the square root relationship between the bandwidth ratio and jitter scaling factor. When the second bandwidth is reduced relative to the Nyquist frequency F_{signal}, the ratio Fₚₗₗ/F_{signal} decreases, resulting in a smaller scaling factor applied to the input jitter Jᵢₙ. This mathematical relationship may enable the system to minimize the impact of reference jitter from the reference clock recovery circuit 305 by appropriately selecting a sufficiently low second bandwidth for the PLL circuit 301.

The VCO intrinsic jitter (Jvco) from the tunable oscillator 362 may represent an additive jitter component that remains constant regardless of the reference jitter level for a given PLL bandwidth configuration. The tunable oscillator 362 may cause or contribute this intrinsic jitter due to thermal noise and phase noise characteristics of the LC/RC oscillator design used in the crystal-less sensor transceiver 325. The total output jitter (Jout) may represent the combination of the scaled reference jitter component and the VCO intrinsic jitter component, where both contributions may affect the quality of the transmission clock used for high data rate transmissions.

In some embodiments, the second bandwidth may be set sufficiently low to filter out residual jitter measurable from the first bandwidth of the CDR loop circuit 230 to the Nyquist frequency of the PLL circuit 301. The residual jitter may thus represent the portion of the jitter spectrum that extends beyond the first bandwidth of the CDR loop circuit 230 and may cause signal-to-noise ratio degradation if not properly managed. By setting the second bandwidth of the PLL circuit 301 below the first bandwidth, the PLL circuit 301 may constrain the jitter spectrum to frequencies that the CDR loop circuit 230 can effectively track and compensate for, thereby reducing the residual jitter that affects the high data rate receiver performance.

In various embodiments, the second bandwidth may be set to a few tens of kilohertz while the PLL circuit 301 operates at a few tens or hundreds of megahertz to achieve effective jitter filtering while maintaining adequate PLL performance for the sensor transceiver 325. This bandwidth range may provide sufficient jitter reduction without excessively increasing the contribution of VCO jitter from the tunable oscillator 362, which may become more prominent at very low PLL bandwidths. The selection of the second bandwidth of the PLL circuit 301 within this range may balance the trade-off between reference jitter filtering and VCO jitter contribution to optimize the overall jitter performance of the transmission clock generated by the PLL circuit 301.

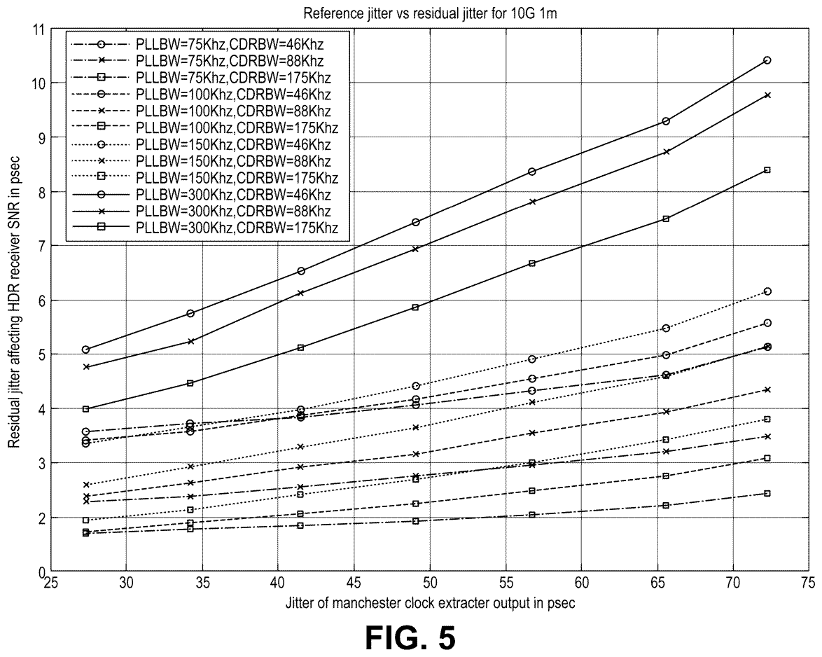

Referring to FIG. 5, a graph illustrates the relationship between reference jitter and residual jitter for an example system with high data rate equal to 10 gigabyte bits/sec (GBPS) on a 1 meter (m) length cable, demonstrating how different combinations of PLL bandwidth and CDR loop bandwidth affect jitter performance in the system 100. The graph depicts the jitter of a Manchester clock extractor output measured in picoseconds on the horizontal axis, ranging from 25 to 75 picoseconds, and residual jitter affecting HDR receiver SNR measured in picoseconds on the vertical axis, ranging from 1 to 11 picoseconds. Multiple curves are plotted representing different combinations of PLL bandwidth and CDR loop bandwidth configurations, where each curve shows how residual jitter varies with increasing Manchester clock extractor output jitter.

The system 100 may define residual jitter as the amount of jitter measured from the CDR loop bandwidth to the Nyquist frequency of PLL operation, which may cause signal-to-noise ratio degradation at the receiver of the central switch transceiver 215. The residual jitter may represent the portion of the jitter spectrum that extends beyond the tracking capability of the CDR loop circuit 230 and may directly impact the quality of data recovery at the central switch transceiver 215. When the CDR loop circuit 230 cannot track jitter components above its bandwidth, these higher frequency jitter components may appear as residual jitter that degrades the SNR of the received high data rate signals from the sensor transceivers 125A-125N.

As shown in FIG. 5, the curves demonstrate that for a given PLL bandwidth, increasing the CDR loop bandwidth may result in lower residual jitter values across the range of Manchester clock extractor output jitter levels. The graph shows configurations with lower PLL bandwidth values, such as 75 KHz, 100 KHz, and 150 KHz, producing lower residual jitter compared to configurations with higher PLL bandwidth values such as 300 KHz. For each PLL bandwidth setting, three different CDR loop bandwidth values are shown: 46 KHz, 88 KHz, and 175 KHz, where higher CDR loop bandwidth values within each PLL bandwidth group may result in reduced residual jitter.

The curves in FIG. 5 indicate that as the Manchester clock extractor output jitter increases, the residual jitter affecting the CDR loop circuit 230 also increases. The rate of increase depends on the specific combination of PLL and CDR loop bandwidths employed. Configurations where the CDR loop bandwidth may be greater than or equal to the PLL bandwidth may demonstrate superior performance in minimizing residual jitter compared to configurations where the CDR bandwidth may be lower than the PLL bandwidth. This relationship may validate the approach of setting the first bandwidth of the CDR loop circuit 230 to be greater than or equal to the second bandwidth of the PLL circuit 301 to achieve effective jitter mitigation.

The residual jitter performance shown in FIG. 5 may directly correlate with signal-to-noise ratio degradation experienced by the central switch transceiver 215 when receiving high data rate signals from the sensor transceiver 325. Lower residual jitter values may correspond to better SNR performance, enabling more reliable data recovery and higher system performance. When the CDR loop circuit 230 operates at a bandwidth that may be greater than or equal to that of the PLL circuit 301 bandwidth, the CDR loop circuit 230 may effectively track the band-limited jitter generated by the PLL circuit 301, thereby reducing the residual jitter that affects the HDR receiver performance.

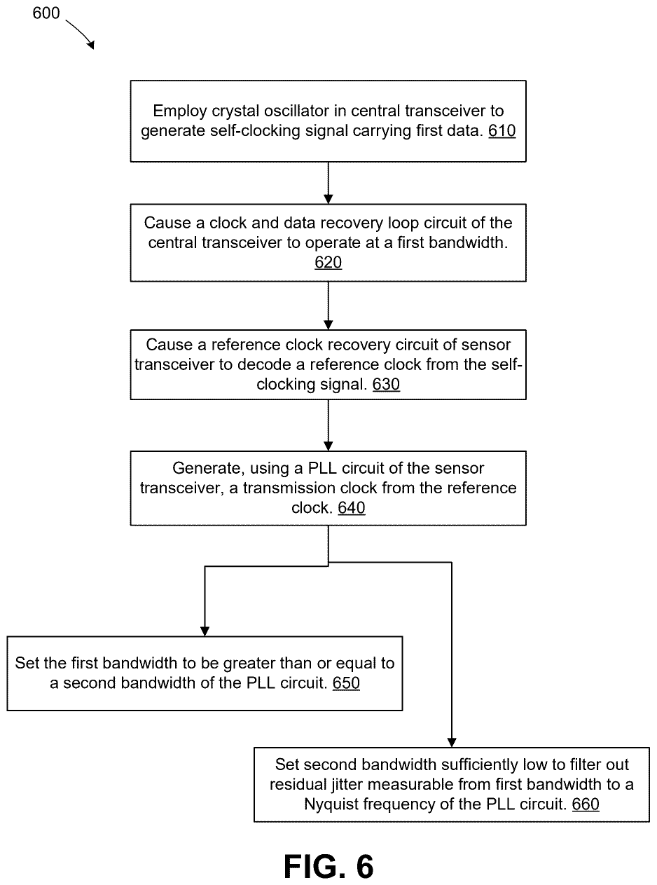

Referring to FIG. 6, a method 600 may be configured for mitigating jitter in crystal-less wireline transceivers through coordinated bandwidth management between central and sensor transceivers. The method 600 may provide a systematic approach to managing jitter in crystal-less transceiver systems by coordinating the bandwidth settings between the central switch transceiver 215 and the sensor transceiver 325 to enable effective jitter tracking and compensation. The method 600 may be implemented in the system 100 to achieve reliable high data rate communication while eliminating the need for individual crystal oscillators at each sensor location.

The method 600 may begin with an operation 610, where the crystal oscillator 201 in the central switch transceiver 215 may be employed to generate the self-clocking signal carrying first data. The crystal oscillator 201 may provide a stable timing reference that serves as the foundation for creating the self-clocking signal transmitted to the sensor transceiver 325. The self-clocking signal may include Manchester coding that embeds timing information within the data transmission, enabling the sensor transceivers to extract both data and timing references from the same signal. The first data carried by the self-clocking signal may include control information and timing references that flow at low data rates from the central switch transceiver 215 to the sensor transceiver 325.

The method 600 may proceed to an operation 620, where the CDR loop circuit 230 of the central switch transceiver 215 may be caused to operate at a first bandwidth. The first bandwidth may determine the ability of the CDR loop circuit 230 to track and compensate for timing variations in signals received from the sensor transceivers 125A-125N. The CDR loop circuit 230 may be configured to recover high data rate information transmitted by the sensor transceivers using their respective transmission clocks generated by the PLL circuit 301. The first bandwidth may be selected to enable effective tracking of band-limited jitter that may be generated by the PLL circuits of the sensor transceivers.

The method 600 may continue to an operation 630, where the reference clock recovery circuit 305 of the sensor transceiver 325 may be caused to decode a reference clock from the self-clocking signal. The reference clock recovery circuit 305 may extract timing information from the Manchester-encoded signal received from the central switch transceiver 215 through XOR gate 370, the delay circuit 374, and the D flip-flop 378. The reference clock recovery circuit 305 may include a Manchester decoder (such as illustrated in FIG. 3C) configured to decode Manchester encoding in the self-clocking signal, enabling the sensor transceiver 325 to derive timing references without requiring a local crystal oscillator. The decoded reference clock may serve as input to the PLL circuit 301 for generating higher frequency transmission clocks.

The method 600 may proceed to an operation 640, where a transmission clock may be generated using the PLL circuit 301 of the sensor transceiver 325 from the reference clock. The PLL circuit 301 may use the reference clock as input to produce a higher frequency clock signal suitable for high data rate transmissions back to the central switch transceiver 215. The PLL circuit 301 may include the phase difference detector 354, the controller 358, the tunable oscillator 362, and the frequency divider 366 (FIG. 3B) that work together to generate the transmission clock from the reference clock. The transmission clock may be distributed to the digital data source 304, the symbol mapper 308, and the TX DAC 312 to synchronize the transmission path operations for generating second data at high data rates.

The method 600 may continue to an operation 650, where the first bandwidth may be set to be greater than or equal to a second bandwidth of the PLL circuit 301. This bandwidth relationship may enable the central switch transceiver 215 to effectively track and compensate for jitter that originates from the PLL circuit 301 of the sensor transceiver 325. When the PLL circuit 301 operates at the second bandwidth that may be lower than or equal to the first bandwidth, the jitter spectrum may be constrained to lower frequencies that the higher bandwidth CDR loop circuit 230 may be capable of tracking without degrading signal-to-noise ratios. The bandwidth relationship can mitigate jitter experienced by the CDR loop circuit 230 due to jitter in the transmission clock generated by the PLL circuit 301.

The method 600 may optionally also proceed to an operation 660, where the second bandwidth may be set sufficiently low to filter out residual jitter measurable from the first bandwidth to a Nyquist frequency of the PLL circuit 301. The residual jitter may represent the portion of the jitter spectrum that extends beyond the tracking capability of the CDR loop circuit 230 and may cause SNR degradation if not properly managed. By setting the second bandwidth sufficiently low, the PLL circuit 301 may constrain the jitter spectrum to frequencies that the CDR loop circuit 230 can effectively track and compensate for, thereby reducing the residual jitter that affects high data rate receiver performance. In some cases, the second bandwidth may be set to tens of kilohertz while the PLL circuit 301 operates at a few tens or hundreds of megahertz, to achieve effective jitter filtering while maintaining adequate PLL performance for the sensor transceiver 325.

The method 600 may enable the system 100 to achieve reliable communication between the central switch transceiver 215 and the sensor transceiver 325 while eliminating the need for individual crystal oscillators at each sensor location. The coordinated bandwidth management approach implemented by the method 600 may reduce system costs and complexity while maintaining acceptable jitter performance through the relationship between the first bandwidth of the CDR loop circuit 230 and the second bandwidth of the PLL circuit 301. The method 600 may be particularly applicable in automotive applications where numerous sensors surround a vehicle and transmit data to a central or zonal switch, enabling cost-effective and reliable sensor network operation.

In various embodiments, the functional interactions between the various components in the crystal-less transceiver system may enable effective jitter mitigation through coordinated signal processing and bandwidth management. The signal flow may begin with the crystal oscillator 201 generating a stable timing reference that serves as the foundation for all timing operations within the central switch transceiver 215. This timing reference may be used by the transmitter circuit to create the self-clocking signal that carries both data and embedded timing information to the sensor transceivers 125A, 125B, 125N, 325.

The self-clocking transmission path may utilize Manchester coding or other self-clocking signaling schemes to embed timing information within the data stream transmitted at low data rates to the sensor transceiver 325. The Manchester coding may ensure that timing transitions occur within the data signal itself, enabling the sensor transceiver 325 to extract both data content and timing references from the same transmitted signal. The hybrid interface circuit 216, 316 may enable this self-clocking signal to be transmitted over the same differential pair that carries high data rate signals in the opposite direction, facilitating efficient bidirectional communication, although bidirectional communication is not required for the principles taught herein to still apply.

At the sensor transceiver 325, the reference clock recovery circuit 305 may process the received self-clocking signal to extract the embedded timing information and generate a reference clock that maintains synchronization with the crystal oscillator 201 at the central switch transceiver 215. This recovered reference clock may serve as the timing foundation for transmission operations of the sensor transceiver.

The PLL circuit 301 may receive the recovered reference clock and generate a high-frequency transmission clock suitable for high data rate transmissions back to the central switch transceiver 215. The PLL circuit 301 can multiply the frequency of the reference clock through its feedback control mechanism, where the phase difference detector 354 compares the reference clock with a divided version of the output clock to maintain phase alignment. The controller 358 may adjust the tunable oscillator 362 based on phase error information to generate the desired high-frequency transmission clock that synchronizes data transmission operations of the sensor transceiver 325.

The bandwidth configuration of the PLL circuit 301 may determine how jitter from the reference clock recovery process propagates to the transmission clock output. When the PLL circuit 301 operates at a lower bandwidth, the low-pass filtering characteristics may constrain the reference jitter to lower frequencies while limiting the total jitter power that reaches the transmission clock. This band-limiting effect may create a jitter spectrum that concentrates energy at frequencies below the PLL bandwidth, enabling more effective tracking by the receiving circuitry at the central switch transceiver 215.

The high-bandwidth CDR loop circuit 230 at the central switch transceiver 215 may track and compensate for the band-limited jitter present in the high data rate signals received from the sensor transceiver 325. The CDR loop circuit 230 may continuously adjust its sampling timing to follow the timing variations in the received signals, effectively tracking jitter components that fall within its bandwidth. When the CDR loop bandwidth exceeds the PLL bandwidth of the sensor transceiver 325, the CDR loop circuit 230 may successfully track substantially all of the jitter components generated by the PLL circuits 301, thereby minimizing the residual jitter that affects signal-to-noise ratio performance.

The coordinated bandwidth relationship between the PLL circuit 301 and CDR loop circuit 230 may enable the system 100 to transform high-frequency white noise jitter from the reference clock recovery process into low-frequency band-limited jitter that can be tracked and compensated by the receiving circuitry. The PLL circuit 301 may act as a low-pass filter for the reference jitter while the CDR loop circuit 230 may act as a tracking filter that follows the band-limited jitter variations. This functional interaction may enable the system 100 to maintain acceptable signal quality despite the inherent jitter introduced by the crystal-less operation of the sensor transceiver 325.

In some embodiments, the system 100 may implement echo cancellation functionality to reduce residual echo of HDR TX DAC 312 signal from the hybrid into the LDR receive path. Echo cancellation may address interference that occurs when high data rate transmission signals from the sensor transceiver 325 leak into the low data rate receive path, potentially affecting the reference clock recovery process. The echo cancellation functionality may identify and subtract the echo components from the received self-clocking signal, improving the quality of the reference clock extraction and reducing jitter in the recovered timing reference.

The echo cancellation may operate by monitoring the high data rate transmission signal and generating a replica of the expected echo signal that would appear in the low data rate receive path. This echo replica may be subtracted from the received self-clocking signal to remove the interference caused by the transmitted high data rate signal. By reducing the residual echo, the echo cancellation functionality may improve the signal-to-noise ratio of the reference clock recovery process and reduce the jitter introduced during timing extraction from the self-clocking signal.

In some configurations, the system 100 may operate over half duplex channels as an alternative to full duplex operation. Half duplex operation may utilize separate time periods for transmission and reception, eliminating the simultaneous bidirectional communication that occurs in full duplex systems. During transmission periods, the sensor transceiver 325 may send high data rate information to the central switch transceiver 215 without receiving self-clocking signals. During reception periods, the central switch transceiver 215 may transmit self-clocking signals to the sensor transceiver 325 without receiving high data rate information.

The half duplex operation may reduce interference between the transmit and receive paths by temporally separating the transmission and reception activities. This temporal separation may eliminate the need for hybrid interface circuits 216, 316 and may reduce the complexity of echo cancellation requirements since transmitted and received signals do not occur simultaneously. The reference clock recovery and PLL operations may continue to function in the half duplex configuration, where the sensor transceiver 325 can maintain timing synchronization during transmission periods using the reference clock extracted during previous reception periods.

The system 100 may also operate using a pair of half duplex channels to provide bidirectional communication capability while maintaining the temporal separation of transmission and reception activities. In this configuration, one half duplex channel may be dedicated to low data rate transmission from the central switch transceiver 215 to the sensor transceiver 325, while another half duplex channel may be dedicated to high data rate transmission from the sensor transceiver 325 to the central switch transceiver 215. This dual half duplex approach may provide the communication bandwidth of full duplex operation while maintaining the interference reduction benefits of temporal separation between transmit and receive operations.

Although the operations of the circuit(s) and block(s) herein are shown and described in a particular order, in some embodiments the order of the operations of each circuit/block may be altered so that certain operations may be performed in an inverse order or so that certain operation may be performed, at least in part, concurrently and/or in parallel with other operations. In other embodiments, instructions or sub-operations of distinct operations may be performed in an intermittent and/or alternating manner.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

1. A system comprising:
a crystal oscillator;
a central switch transceiver, coupled to the crystal oscillator, comprising:
a transmitter circuit to employ a timing reference from the crystal oscillator to generate a self-clocking signal carrying first data; and
a clock and data recovery loop circuit to operate at a first bandwidth to sample second data received from a sensor transceiver; and
the sensor transceiver comprising:
a reference clock recovery circuit to decode, from the self-clocking signal, a reference clock; and
a phase-locked loop (PLL) circuit to generate a transmission clock, from the reference clock, for use in generating the second data, wherein the first bandwidth is greater than or equal to a second bandwidth of the PLL circuit to mitigate jitter experienced by the clock and data recovery loop circuit due to jitter in the transmission clock.

2. The system of claim 1, wherein the second bandwidth is set sufficiently low to filter out residual jitter measurable from the first bandwidth to a Nyquist frequency of the PLL circuit.

3. The system of claim 1, wherein the second bandwidth is set to a few tens of kilohertz while the PLL circuit operates at a few tens or hundreds of megahertz.

4. The system of claim 1, wherein the sensor transceiver further comprises digital-to-analog converter circuitry configured to use the transmission clock in generating the second data.

5. The system of claim 1, wherein the central switch transceiver transmits at a low data rate (LDR) and the sensor transceiver receives at a high data rate (HDR) that is higher than the LDR.

6. The system of claim 1, wherein the self-clocking signal comprises Manchester coding.

7. The system of claim 1, wherein the reference clock recovery circuit comprises a Manchester decoder configured to decode Manchester encoding in the self-clocking signal.

8. A central switch comprising:
a crystal oscillator configured to generate a timing reference; and
a central switch transceiver, coupled to the crystal oscillator, comprising:
a transmitter circuit configured to generate a self-clocking signal carrying low data rate information using the timing reference; and
a receiver circuit comprising a clock and data recovery loop circuit configured to operate at a first bandwidth to recover high data rate information from a sensor transceiver, wherein the first bandwidth is configured to be greater than or equal to a phase-locked loop (PLL) bandwidth of the sensor transceiver to mitigate jitter experienced from the self-clocking signal.

9. The central switch of claim 8, wherein the self-clocking signal comprises Manchester coding.

10. The central switch of claim 8, wherein the transmitter circuit is configured to operate at a low data rate and the receiver circuit is configured to recover high data rate information that is higher than the low data rate.

11. The central switch of claim 10, wherein the low data rate is used for transmission to the sensor transceiver and the high data rate is used for reception from the sensor transceiver in an asymmetric communication configuration.

12. The central switch of claim 8, wherein the first bandwidth is configured to track and compensate for band-limited jitter generated by PLL circuits of the sensor transceiver.

13. The central switch of claim 12, wherein the band-limited jitter comprises low-frequency jitter components that survive low-pass filtering by the PLL bandwidth of the sensor transceiver.

14. The central switch of claim 8, wherein the central switch transceiver further comprises a hybrid interface circuit configured to enable transmission and reception over a single differential pair of conducting medium.

15. A sensor transceiver comprising:
a reference clock recovery circuit configured to extract a reference clock from a self-clocking signal transmitted received from a central switch transceiver;
a phase-locked loop (PLL) circuit configured to generate a high frequency transmission clock from the reference clock, the PLL circuit having a bandwidth that is less than or equal to a clock and data recovery (CDR) loop bandwidth of the central switch transceiver; and
a transmitter circuit configured to transmit high data rate information using the high frequency transmission clock.

16. The sensor transceiver of claim 15, wherein the reference clock recovery circuit comprises a Manchester decoder configured to decode Manchester encoding in the self-clocking signal.

17. The sensor transceiver of claim 15, wherein the self-clocking signal is received at a low data rate and the high data rate information is transmitted at a rate that is higher than the low data rate.

18. The sensor transceiver of claim 15, wherein the bandwidth is set sufficiently low to filter out residual jitter measurable from the CDR loop bandwidth to a Nyquist frequency of the PLL circuit.

19. The sensor transceiver of claim 15, wherein the PLL circuit comprises:
a phase difference detector configured to identify a phase difference between the reference clock and a divided output from a voltage controlled oscillator;
a controller configured to adjust the voltage controlled oscillator based on the phase difference; and
a frequency divider in a feedback path configured to divide the voltage controlled oscillator output by an integer factor, wherein the bandwidth of the PLL circuit is determined by a transfer function of the controller, a loop gain, and a rate of the reference clock.

20. The sensor transceiver of claim 15, further comprising a hybrid interface circuit configured to enable transmission and reception on a single differential pair of conducting medium.
